(19) United States
(12) Patent Application Publication
(10) Pub. No.: US 2026/0247849 A1
(43) Pub. Date: Aug. 20, 2026

(54) DISPLAY DEVICE AND METHOD FOR FABRICATING THE SAME

(71) Applicant: Samsung Display Co., LTD., Yongin-si (KR)

(72) Inventors: Jae Youl KIM, Yongin-si (KR); Kyong Sub KIM, Yongin-si (KR); Yoon Seok KA, Yongin-si (KR)

(21) Appl. No.: 19/305,949

(22) Filed: Aug. 21, 2025

(30) Foreign Application Priority Data
Feb. 17, 2025 (KR) 10-2025-0020212

(51) Int. Cl. H10K 71/20; C09K 11/02; H10K 50/16; H10K 59/12

(52) U.S. Cl. CPC H10K 71/211; C09K 11/025; H10K 50/166; H10K 59/1201

(57) ABSTRACT

A display device, an electronic device including the display device, and a method of manufacturing the display device. The method for fabricating a display device includes: forming a first electrode on a substrate; forming an emissive layer on the first electrode; and treating the emissive layer with an organic acid represented by the following chemical formula:

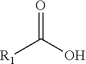

wherein R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

This application is based on and claims priority to Korean Patent Application No. 10-2025-0020212 filed on Feb. 17, 2025 in the Korean Intellectual Property Office, and all the benefits accruing therefrom under 35 U.S.C. § 119, the content of which is incorporated herein by reference in its entirety.

### BACKGROUND

### 1. Field of the Disclosure

The present disclosure relates to a display device, an electronic device including the display device, and a method for fabricating the display device.

### 2. Description of the Related Art

As the information-oriented society evolves, various demands for display devices are ever increasing. For example, display devices are being employed by a variety of electronic devices such as smart phones, digital cameras, laptop computers, navigation devices, and smart televisions.

Display devices may be flat panel display devices such as a liquid-crystal display device, a field emission display device, and a light-emitting display device. Light-emitting display devices may include an organic light-emitting display device including an organic light-emitting element, an inorganic light-emitting display device including an inorganic light-emitting element such as an inorganic semiconductor, and a micro-light-emitting display device including an ultra-small light-emitting element.

In order to improve the color gamut of display devices, light-emitting elements using quantum dots as light-emitting materials are under development. Accordingly, it is desirable to improve the emission efficiency and lifespan of light-emitting elements using quantum dots. An aging process may be performed to stabilize the display devices.

### SUMMARY

Aspects of the present disclosure provide a display device including a quantum-dot light-emitting element having excellent emission efficiency by treating a target layer with an organic acid during the fabrication process.

It should be noted that objects of the present disclosure are not limited to the above-mentioned object; and other objects of the present disclosure will be apparent to those skilled in the art from the following descriptions.

According to an aspect of embodiments of the present disclosure, there may be provided a method for fabricating a display device, the method including: forming a first electrode on a substrate; forming an emissive layer on the first electrode; and treating the emissive layer with an organic acid represented by the following chemical formula:

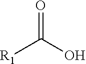

wherein R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

A concentration of the organic acid may be equal to or less than 10 weight percent (wt %) % based on the weight of the ______.

An acid dissociation constant (pKa) of the organic acid may be 1.0 to 5.5.

The treating the emissive layer with the organic acid may include: placing the substrate having the emissive layer formed thereon inside a reaction space; and vaporizing the organic acid at a temperature of 70° C. or lower and injecting it into the reaction space.

The reaction space may be a vacuum chamber dryer (VCD) or a vapor chamber.

The treating the emissive layer with the organic acid may be performed for 30 minutes to 120 hours.

The forming the emissive layer on the first electrode, and treating the emissive layer with the organic acid include: forming a first emissive layer emitting light of a first wavelength range in a first emission area; treating the first emissive layer with the organic acid derivative; forming a second emissive layer emitting light of a second wavelength range in a second emission area; treating the first emissive layer and the second emissive layer with the organic acid derivative; forming a third emissive layer emitting light of a third wavelength range in a third emission area; and treating the first emissive layer, the second emissive layer and the third emissive layer with the organic acid derivative.

The first wavelength range may be lower than the second wavelength range, and the second wavelength range is lower than the third wavelength range.

The first emissive layer may include a first hole transport layer, a first hole injection layer, a first quantum-dot emissive layer, a first electron transport layer and a first electron injection layer, wherein the second emissive layer includes a second hole transport layer, a second hole injection layer, a second quantum-dot emissive layer, a second electron transport layer, and a second electron injection layer, and wherein the third emissive layer includes a third hole transport layer, a third hole injection layer, a third quantum-dot emissive layer, a third electron transport layer, and a third electron injection layer.

The forming the emissive layer on the first electrode, and treating the emissive layer with the organic acid may include: sequentially forming the first hole injection layer, the first hole transport layer, the first quantum-dot emissive layer, and the first electron transport layer on the first electrode in the first emission area; treating the first electron transport layer with the organic acid derivative; sequentially forming the second hole injection layer, the second hole transport layer, the second quantum-dot emissive layer, and the second electron transport layer on the first electrode in the second emission area; treating the second electron transport layer with the organic acid derivative; sequentially forming the third hole injection layer, the third hole transport layer, the third quantum-dot emissive layer, and the third electron transport layer on the first electrode in the third emission area; and treating the third electron transport layer with the organic acid derivative.

The forming the emissive layer may further include: forming an electron injection layer on the first electron transport layer, the second electron transport layer, and the third electron transport layer.

The forming the emissive layer, and treating the emissive layer with the organic acid may include: sequentially forming an electron injection layer and an electron transport layer on the first electrode; and treating the electron transport layer with the organic acid derivative.

The method may further include: sequentially forming a quantum-dot emissive layer, a hole transport layer and a hole injection layer on the electron transport layer.

The electron transport layer may include a metal oxide.

The method may further include: forming a second electrode on the emissive layer.

According to an aspect of embodiments of the present disclosure, there may be provided a display device may include: a substrate; a first electrode on the substrate; an emissive layer on the first electrode; and a second electrode on the emissive layer, wherein the emissive layer is treated with an organic acid represented by the following chemical formula, wherein the emissive layer may include: a first emissive layer emitting light of a first wavelength range in a first emission area; a second emissive layer emitting light of a second wavelength range in a second emission area; and a third emissive layer emitting light of a third wavelength range in a third emission area, and wherein a degree to which the first emissive layer is treated with the organic acid, a degree to which the second emissive layer is treated with the organic acid, and a degree to which the third emissive layer is treated with the organic acid are different from one another:

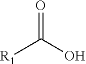

where R₁ may be H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

The display device further includes an electron transport region including a metal oxide located on the emissive layer.

The electron transport region may include: a first electron transport region in line with first emission area in a thickness direction of the substrate; a second electron transport region in line with the second emission area in the thickness direction of the substrate; and a third electron transport region in line with the third emission area in the thickness direction of the substrate.

A flash point of the organic acid may be equal to or less than 70° C. at atmospheric pressure.

According to an aspect of embodiments of the present disclosure, there may be provided an electronic device including: a display device providing images; and a processor configured to transmit an image data signal to the display device, wherein the display device is fabricated by: forming a first electrode on a substrate; forming an emissive layer on the first electrode; and treating the emissive layer with an organic acid represented by the following chemical formula:

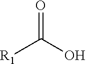

where R₁ may be H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

According to embodiments of the present disclosure, only a target layer is treated with the vapor of an organic acid in a display device, so that it is possible to prevent excessive acid treatment. In particular, if an encapsulation layer containing an acid is on a light-emitting element, the acid of the encapsulation layer may leak into the light-emitting element, and thus the deterioration of the light-emitting element may increase. In contrast, according to the present disclosure, it is possible to prevent excessive acid treatment because acid treatment is performed only during the fabrication process.

In addition, charge balance may be improved, leakage current may be reduced, and the quenching phenomenon may be suppressed in the light-emitting element.

Moreover, the degree of the treatment with the organic acid may be adjusted depending on different regions, so that the emission efficiency may be improved.

It should be noted that effects of the present disclosure are not limited to those described above and other effects of the present disclosure will be apparent to those skilled in the art from the following descriptions.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view showing a display device according to an embodiment of the present disclosure.

FIG. 2 is a cross-sectional view taken along line A-A′ of FIG. 1.

FIG. 3 is a cross-sectional view showing the display panel according to the embodiment of the present disclosure.

FIG. 4 is an enlarged cross-sectional view of area LE of FIG. 3, showing the structure of a light-emitting element according to a first embodiment.

FIG. 5 shows a structure in which the hole injection layer HIL and the hole transport layer HTL are reversed with the electron transport layer ETL and the electron injection layer EIL of FIG. 4.

FIG. 6 is a flowchart for illustrating a method for fabricating a display device according to an embodiment of the present disclosure.

FIG. 7 is a cross-sectional view showing a substrate and a plurality of first electrodes at step S100 of FIG. 6.

FIG. 8 is a cross-sectional view showing the substrate, the first electrodes, and the emissive layers at step S200 of FIG. 6.

FIG. 9 is a view showing injecting the organic acid into a reaction space where the substrate on which emissive layers are formed is placed at step S300 of FIG. 6.

FIG. 10 is a cross-sectional view showing a first electrode, a first hole injection layer, a first hole transport layer, a first quantum-dot emissive layer, and a first electron transport layer in a first emission area.

FIG. 11 is a view showing injecting the organic acid into a reaction space where a substrate is placed, on which a first electrode, a first hole injection layer, a first hole transport layer, a first quantum-dot emissive layer, and a first electron transport layer are formed in a first emission area.

FIG. 12 is a cross-sectional view showing a first electrode, a second hole injection layer, a second hole transport layer, a second quantum-dot emissive layer, and a second electron transport layer in a second emission area.

FIG. 13 is a view showing injecting the organic acid into the reaction space where the substrate is placed, on which a first electrode, a second hole injection layer, a second hole transport layer, a second quantum-dot emissive layer, and a second electron transport layer are formed in the second emission area.

FIG. 14 is a cross-sectional view showing a first electrode, a third hole injection layer, a third hole transport layer, a third quantum-dot emissive layer, and a third electron transport layer in a third emission area.

FIG. 15 is a view showing injecting the organic acid into the reaction space where the substrate is placed, on which a first electrode, a third hole injection layer, a third hole transport layer, a third quantum-dot emissive layer, and a third electron transport layer are formed in a third emission area.

FIG. 16 is a cross-sectional view showing a first electrode, a hole injection layer, a hole transport layer, a quantum-dot emissive layer, an electron transport layer, an electron injection layer, and a second electrode.

FIG. 17 is a graph showing the luminance over time of the light-emitting elements of Example 1, Comparative Example 1, and Comparative Example 2.

FIG. 18 is a block diagram of an electronic device according to an embodiment of the present disclosure.

FIG. 19 is a view showing electronic devices according to a variety of embodiments of the present disclosure.

### DETAILED DESCRIPTION OF THE EMBODIMENTS

The advantages and features of the present invention, and the methods for achieving them, will become clear with reference to the embodiments described below in detail with the accompanying drawings. However, the present invention is not limited to the embodiments disclosed below, but may be implemented in various different forms, and these embodiments are provided only to make the disclosure of the present invention complete and to fully inform those skilled in the art of the invention of the scope of the invention, and the present invention is defined only by the scope of the claims.

When elements or layers are referred to as “on” another element or layer, this includes all cases where another layer or another element is interposed directly over or in the middle of the other element. The same reference numerals refer to the same components throughout the specification. The shapes, sizes, ratios, angles, numbers, or the like disclosed in the drawings for explaining the embodiments are exemplary, and therefore the present invention is not limited to the matters illustrated.

Although the terms “first” and “second” are used to describe various components, these components are not limited by these terms. These terms are only used to distinguish one component from another. Therefore, it goes without saying that the first component mentioned below may be the second component within the technical idea of the present invention. The features of each of the various embodiments of the present invention may be partially or wholly combined or combined with each other, and various technical connections and operations are possible, and each embodiment may be implemented independently of each other or may be implemented together in a related relationship.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. Therefore, reference to “an” element in a claim followed by reference to “the” element is inclusive of one element as well as a plurality of the elements.

It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

The term “treating” as used herein is inclusive of contacting a reactant with an article to be reacted upon.

The R₁ groups as defined herein may be substituted or unsubstituted with one or more (e.g., 1, 2, 3, or 4) substituents that may be the same or different, up to the allowable valence of the group. Possible substituents include but are not limited hydroxyl (—OH), a C₁₋₆ alkoxy, a C₁₋₆ haloalkoxy, an oxo (═O)), a nitro (—NO₂), a cyano (—CN), an amino (—NH₂), an amidino (—C(═NH)NH₂), a hydrazino (—NHNH₂), a hydrazono (═N—NH₂), a carbonyl (—C(═O)—), a carbamoyl (—C(O)NH₂), a sulfonyl (—S(═O)₂—), a thiol (—SH), a thiocyano (—SCN), a tosyl (CH₃C₆H₄SO₂—), a carboxylic C₁₋₇ alkyl or alkenyl ester (—C(═O)OR wherein R is a C₁₋₆ alkyl or C₂₋₆ alkenyl), -), a C₂₋₇ oxycarbonyl alkyl (—OC(═O)R wherein R is a C₁₋₆ alkyl or C₂₋₆ alkenyl), a C₁₋₆ alkyl, a C₃₋₆ cycloalkyl, a C₂₋₆ alkenyl, or a C₂₋₆ alkynyl.

Hereinafter, exemplary embodiments of the present disclosure will be described with reference to the accompanying drawings.

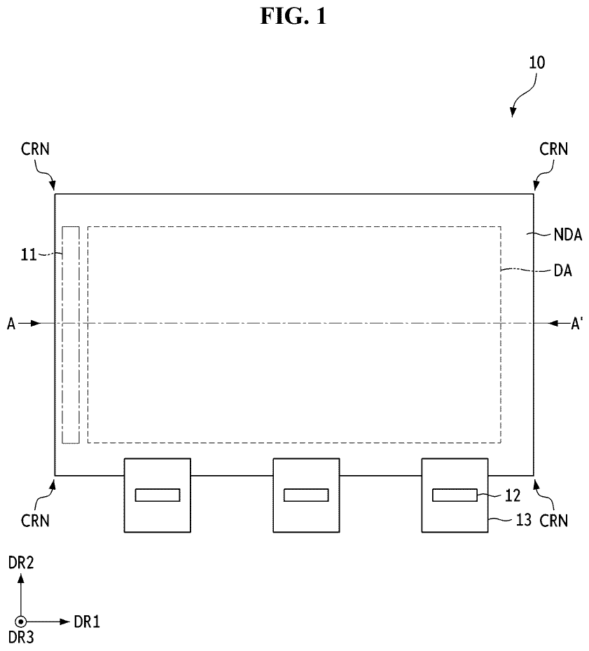

FIG. 1 is a plan view showing a display device according to an embodiment of the present disclosure.

Referring to FIG. 1, a display device 10 according to an embodiment of the present disclosure is for displaying moving images or still images. The display device 10 may be used as the display screen of portable electronic devices such as a mobile phone, a smart phone, a tablet PC, a smart watch, a watch phone, a mobile communications terminal, an electronic notebook, an electronic book, a portable multimedia player (PMP), a navigation device and a ultra mobile PC (UMPC), as well as the display screen of a variety of electronic devices such as a television, a notebook, a monitor, a billboard and the Internet of Things (IoT) devices.

The display device 10 may be a light-emitting display device such as an organic light-emitting display device using organic light-emitting diodes, a quantum-dot light-emitting display device including a quantum-dot emissive layer, an inorganic light-emitting display device including an inorganic semiconductor, and a micro light-emitting display device using micro or nano light-emitting diodes (micro LEDs or nano LEDs). In the following description, a quantum-dot light-emitting display device is employed as the display device 10. It should be understood, however, that the present disclosure is not limited thereto. An organic light-emitting display device, an inorganic light-emitting display device, or a micro light-emitting display device may be employed as the display device.

The display device 10 may be formed flat, but the present disclosure is not limited thereto. For example, the display device 10 may include curved portions that are formed at left and right ends and have a constant curvature or varying curvatures. In addition, the display device 10 may be flexible so that it may be curved, bent, folded, or rolled.

According to an embodiment, the display device 10 may be an organic light-emitting display device.

As shown in FIG. 1, the display device 10 according to the embodiments may include a surface of a rectangular shape. It should be understood, however, that this is merely illustrative. The shape of the display device 10 is not limited to that shown in FIG. 1. That is to say, the display device 10 according to the embodiments may include a surface of a polygonal shape other than a rectangular shape, or a circular shape. Alternatively, at least a part of the display device 10 may be deformed from an unfolded shape to a bent, curved, folded, or rolled shape.

The surface of the display device 10 may include a display area DA where light is output for displaying images, and a non-display area NDA surrounding the display area DA.

The display area DA may be located over most of the surface of display device 10.

The non-display area NDA may be an area in a frame shape surrounding the display area DA where no light for displaying images is output. For example, the non-display area NDA may be maintained in a particular color such as black.

The surface of the display device 10 may include corners CRN where the intersecting sides meet each other. For example, if the surface of the display device 10 is in a rectangular shape, it may include four corners CRN.

The display device 10 may include drivers 11 and 12 that transmit signals, voltages or power to emission pixel drivers arranged in the display area DA.

Among the drivers 11 and 12, some of the drivers 11 that may be implemented with relatively simple circuits may be placed in the non-display area NDA.

Some others of the drivers 11 and 12 may be implemented as integrated circuit chips and may be mounted on circuit boards 13 electrically connected to pads in the non-display area NDA. Alternatively, some other drivers 12 may be mounted on the pads in the non-display area NDA.

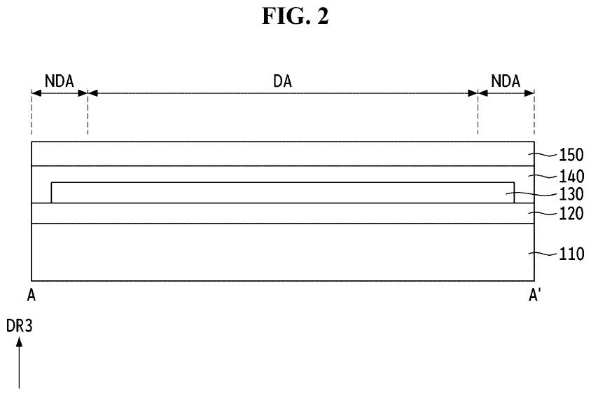

FIG. 2 is a cross-sectional view taken along line A-A′ of FIG. 1.

Referring to FIG. 2, the display device 10 according to an embodiment of the present disclosure may include a display area DA where light for displaying images is output, and a non-display area NDA around the display area DA where no light is output.

According to the embodiment, the display device 10 may include a substrate 110 including the display area DA and the non-display area NDA, and a circuit layer 120, an element layer 130, an encapsulation layer 140 and a color filter layer 150 arranged on the substrate 110.

The element layer 130 may be arranged on the circuit layer 120.

Specifically, according to the embodiment, the display device 10 may include the substrate 110, the circuit layer 120 on the substrate 110, the element layer 130 on the circuit layer 120, the encapsulation layer 140 on the element layer 130, and the color filter layer 150 on the encapsulation layer 140.

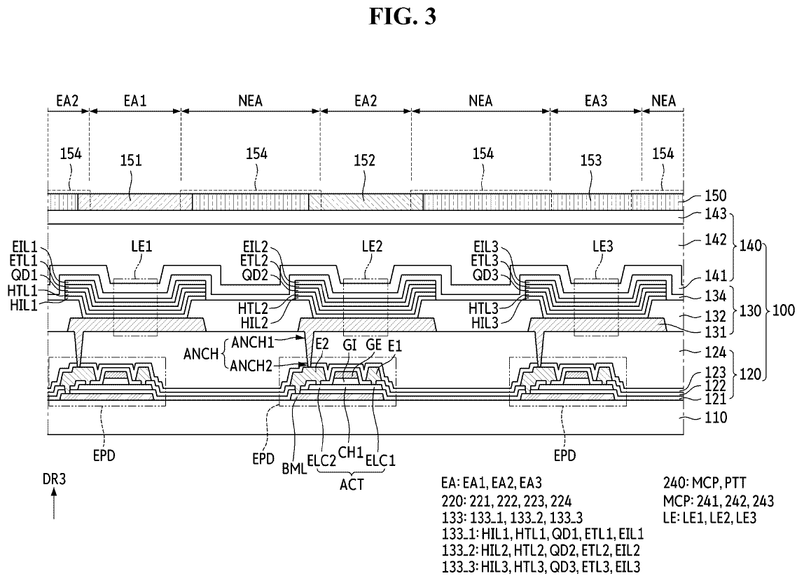

FIG. 3 is a cross-sectional view showing the display panel according to the embodiment of the present disclosure.

Referring to FIG. 3, the display device 10 may include the substrate 110, the circuit layer 120 arranged on the substrate 110, the element layer 130 including light-emitting elements LE (LE1, LE2, LE3) arranged in emission areas EA on the circuit layer 120, the encapsulation layer 140 covering the element layer 130, and the color filter layer 150 on the encapsulation layer 140. Light emitted from the light-emitting elements LE of the element layer 130 may pass through the color filter layer 150 to exit to the outside.

The substrate 110 may include the display area DA (see FIG. 1) and the non-display area NDA (see FIG. 1).

The display area DA may include the emission areas EA1, EA2 and EA3 (EA in FIG. 3) arranged in parallel and the non-emission area NEA between the emission areas EA1, EA2 and EA3 (EA in FIG. 3).

The circuit layer 120 may include a buffer layer 121 on the substrate 110, a first interlayer dielectric layer 122 on the buffer layer 121, a second interlayer dielectric layer 123 on the first interlayer dielectric layer 122, and a planarization layer 124 on the second interlayer dielectric layer 123.

Each of the buffer layer 121, the first interlayer dielectric layer 122 and the second interlayer dielectric layer 123 may include an inorganic insulating material.

The planarization layer 124 may include an organic insulating material.

The circuit layer 120 may include emission pixel drivers EPD that transmit driving current to light emitting elements LE.

Each of the emission pixel drivers EPD may include two or more transistors and may be electrically connected to one or more lines.

The first transistor of each of the emission pixel drivers EPD may include an active layer ACT on the buffer layer 121, a gate insulator GI covering a channel CH1 of the active layer ACT, a gate electrode GE on the gate insulator GI, and a first transistor electrode E1 and a second transistor electrode E2 arranged on the first interlayer dielectric layer 122 covering the active layer ACT and the gate electrode GE.

At least the channel CH1 of the active layer ACT may overlap with a light-blocking layer BML on the substrate 110.

The buffer layer 121 may cover the light-blocking layer BML.

The active layer ACT may include the channel CH1, a first transistor electrode portion ELC1 connected to one side of the channel CH1, and a second transistor electrode portion ELC2 connected to the opposite side of the channel CH1.

The first transistor electrode E1 may be electrically connected to the first transistor electrode portion ELC1 of the active layer ACT through a hole penetrating the first interlayer dielectric layer 122.

The second transistor electrode E2 may be electrically connected to the second transistor electrode portion ELC2 of the active layer ACT through a hole penetrating the first interlayer dielectric layer 122.

The second transistor electrode E2 may be electrically connected to the light-blocking layer BML through a hole penetrating the first interlayer dielectric layer 122 and the buffer layer 121.

The upper surface of the channel CH1 may face the gate electrode GE, and the rear surface of the channel CH1 may face the light-blocking layer BML electrically connected to the second transistor electrode E2.

Accordingly, depending on the potential of the light-blocking layer BML that is equal to the second transistor electrode E2, a portion of the active layer ACT which is adjacent to the light-blocking layer BML may be activated relatively weakly compared to another portion adjacent to the gate electrode GE.

The second interlayer dielectric layer 123 may cover the first interlayer dielectric layer 122, the first transistor electrode E1, and the second transistor electrode E2.

The planarization layer 124 may cover the second interlayer dielectric layer 123 and may include an organic insulating material.

The element layer 130 may be arranged on the planarization layer 124 of the circuit layer 120.

The element layer 130 includes light-emitting elements LE arranged in the emission areas EA.

Each of the light-emitting elements LE may include a structure in which an emissive layer 133 is arranged between a first light-emitting electrode 131 and a second light-emitting electrode 134 facing each other.

Specifically, the element layer 130 may include first light-emitting electrodes 131 arranged in the emission areas EA on the circuit layer 120, a pixel-defining layer 132 arranged in the non-emission area NEA on the circuit layer 120 and covering the edges of the first light-emitting electrodes 131, the emissive layer 133 arranged on the first light-emitting electrodes 131, and the second light-emitting electrode 134 arranged on the emissive layer 133.

The emissive layer 133 may be arranged in each of the emission areas EA, which may be spaced apart from another one. A first emissive layer 1331 in a first emission area EA1 may emit light of a first wavelength range. A second emissive layer 133_2 in a second emission area EA2 may emit light of a second wavelength range. A third emissive layer 133_3 in a third emission area EA3 may emit light of a third wavelength range.

The first light-emitting electrodes 131 may be electrically connected to the emission pixel drivers EPD through anode connection holes ANCH, respectively.

Specifically, the first light-emitting electrode 131 may be electrically connected to the second transistor electrode E2 of the first transistor ST1 of the emission pixel driver EPD through the anode connection hole ANCH.

The anode connection holes ANCH may penetrate the planarization layer 124 and the second interlayer dielectric layer 123.

The first light-emitting electrode 131 has conductivity. The first light-emitting electrode 131 may be formed of a metal alloy or a conductive compound. The first light-emitting electrode 131 may be an anode. The first light-emitting electrode 131 may be a pixel electrode.

In the light-emitting element LE according to the embodiment, the first light-emitting electrode 131 may be a reflective electrode. It is, however, to be understood that embodiments of the present disclosure are not limited thereto. For example, the first light-emitting electrode 131 may be a transmissive electrode or a translucent electrode. When the first light-emitting electrode 131 is a translucent electrode or a reflective electrode, the first light-emitting electrode 131 may include Ag, Mg, Cu, Al, Pt, Pd, Au, Ni, Nd, Ir, Cr, Li, Ca, LiF/Ca, LiF/Al, Mo, Ti, or a compound or mixture thereof (e.g., a mixture of Ag and Mg). Alternatively, the first light-emitting electrode 131 may have a multi-layer structure including a reflective film or translucent film formed with the above materials and a transparent conductive film formed with ITO (indium tin oxide), IZO (indium zinc oxide), ZnO (zinc oxide), ITZO (indium tin zinc oxide), or the like For example, the first light-emitting electrode 131 may be a multilayer metal film, in which metal films of ITO/Ag/ITO are stacked on one another.

The pixel-defining layer 132 may include an insulating material.

The emissive layer 133 may include quantum dots.

The quantum dots refer to crystals of semiconductor compounds. The quantum dots may emit light of different wavelengths depending on the size of the crystals. The quantum dots may emit light of various wavelengths by controlling the element ratio in the quantum dot compound.

The first emissive layer 1331 may include quantum dots that emit light in the first wavelength range. The second emissive layer 133_2 may include quantum dots that emit light in the second wavelength range. The third emissive layer 1333 may include quantum dots that emit light in the third wavelength range.

The first wavelength range may be lower than the second wavelength range, and the second wavelength range may be lower than the third wavelength range. The first wavelength range may be a blue wavelength range, the second wavelength range may be a green wavelength range, and the third wavelength range may be a red wavelength range. For example, the blue wavelength range may refer that the main peak wavelength of light lies in the wavelength range of approximately 370 nanometers (nm) to 460 nm, the green wavelength range may refer that the main peak wavelength of light lies in the wavelength range of approximately 480 nm to 560 nm, and the red wavelength range may refer to that the main peak wavelength of light lies in the wavelength range of approximately 600 nm to 750 nm.

The diameter of the quantum dots may be, e.g., approximately 1 nm to 10 nm. The quantum dots may be synthesized by a wet chemical process, an organometallic chemical vapor deposition process, a molecular-beam epitaxy process, or a similar process.

The cores of the quantum dots may be group II-VI compounds, group III-V compounds, group III-VI compounds, group I-III-VI compounds, group IV-VI compounds, group IV elements, group IV compounds, or a combination thereof.

The group II-VI compounds may be binary compounds of CdSe, CdTe, CdS, ZnS, ZnSe, ZnTe, ZnO, HgS, HgSe, HgTe, MgSe, MgS or a combination thereof; ternary compounds of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS or a combination thereof; and quaternary compounds of HgZnTeS, CdZnSeS, CdZnSeTe, CdZnSTe, CdHgSeS, CdHgSeTe, CdHgSTe, HgZnSeS, HgZnSeTe, HgZnSTe or a combination thereof. The group II-VI semiconductor compounds may further include group I metal and/or group IV element. The group I-II-VI compounds may be CuSnS or CuZnS, and Group II-IV-VI compounds may be ZnSnS, or the like. The group I-II-IV-VI compounds may be a quaternary compound of: Cu₂ZnSnS₂, Cu₂ZnSnS₄, Cu₂ZnSnSe₄, Ag₂ZnSnS₂ or a combination thereof.

The group III-VI compounds may include binary compounds such as In₂S₃, In₂Se₃, ternary compounds such as InGaS₃, InGaSe₃, or a combination thereof.

The group I-III-VI compounds may be ternary compounds of: AgInS, AgInS₂, CuIns, CuInS₂, AgGaS₂, CuGaO₂, AgGaO₂, AgAlO₂ or a combination thereof, or quaternary compounds such as AgInGaS₂ and CuInGaS₂.

The group III-V compounds may be binary compounds of GaN, GaP, GaAs, GaSb, AlN, AlP, AlAs, AlSb, InN, InP, InAs, InSb or a combination thereof; ternary compounds of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb or a combination thereof; or quaternary compounds of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb or a combination thereof. The group III-V compounds may further include group II metals. For example, InZnP and the like may be selected as group III-II-V compounds.

The group IV-VI compounds may be binary compounds of SnS, SnSe, SnTe, PbS, PbSe, PbTe or a combination thereof; ternary compounds of SnSeS, SnSeTe, SnSTe, PbSeS, PbSeTe, PbSTe, SnPbS, SnPbSe, SnPbTe or a combination thereof; and quaternary compounds of SnPbSSe, SnPbSeTe, SnPbSTe or a combination thereof.

Examples of the group II-IV-V semiconductor compounds may be ternary compounds of: ZnSnP, ZnSnP₂, ZnSnAs₂, ZnGeP₂, ZnGeAs₂, CdSnP₂, CdGeP₂, or a combination thereof.

The group IV elements may be Si, Ge, or a combination thereof. The group IV compounds may be binary compounds of SiC, SiGe, or a combination thereof.

Each element included in a multi-element compound such as a binary compound, a ternary compound, and a quaternary compound may exist in the particles at a uniform or non-uniform concentration. That is to say, the chemical formula representing quantum dots may refer to the type of element included in the quantum dot compound, and the element ratio in the compound may be different. For example, AgInGaS₂ may refer to AgInxGa₁₋ₓS₂, where x is a real number between 0 and 1.

The binary compounds, the ternary compounds or the quaternary compounds may be present in the particles at a uniform concentration, or may be present in the same particles at partially different concentrations. In addition, they may have a core/shell structure in which one quantum dot surrounds another quantum dot. In the core/shell structure, the gradient of the concentration of atoms exiting in the shell may decrease toward the core.

In some embodiments, the quantum dots may have a core-shell structure including a core including the nanocrystals and a shell surrounding the core. The shells of the quantum dots may serve as a protective layer for maintaining the semiconductor properties by preventing chemical denaturation of the core and/or as a charging layer for imparting electrophoretic properties to the quantum dots. The shell may be either a single layer or multiple layers. Examples of the shell of the quantum dot may include an oxide of a metal or a non-metal, a semiconductor compound, a combination thereof, or the like

For example, examples of the metal or non-metal oxide may include, but is not limited to, binary compounds such as SiO₂, Al₂O₃, TiO₂, ZnO, MnO, Mn₂O₃, Mn₃O₄, CuO, FeO, Fe₂O₃, Fe₃O₄, CoO, Co₃O₄ and NiO or ternary compounds such as MgAl₂O₄, CoFe₂O₄, NiFe₂O₄ and CoMn₂O₄.

Examples of the semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, or the like

The quantum dots may have a full width at half maximum (FWHM) of the emission wavelength spectrum of approximately 45 nm or less, preferably approximately 40 nm or less, more preferably approximately 30 nm or less. Within the above ranges, the color purity and color gamut may be improved. In addition, the lights emitted through the quantum dots exit in all directions, so that the viewing angle may be widened.

The shape of the quantum dots is not particularly limited and may have any shape known in the art. More specifically, the quantum dots may have a spherical shape, a pyramidal shape, or a multi-arm shape, or may be cubic nanoparticles, nanotubes, nanowires, nanofibers, nano-platelets, or the like.

Since the energy band gap of quantum dots may be controlled by adjusting the size of the quantum dots or the element ratio in the quantum dot compound, light of various wavelengths may be obtained from the quantum-dot emissive layer. Therefore, by using quantum dots as described above (using quantum dots of different sizes or having different element ratios in the quantum dot compound), it is possible to implement a light-emitting element that emits light of various wavelengths.

The second light-emitting electrode 134 may be arranged in the display area DA including the emission areas EA1, EA2 and EA3; EA in FIG. 3) and the non-emission area NEA.

The second light-emitting electrode 134 may be a common electrode or a cathode. The second light-emitting electrode 134 may be a transmissive electrode, a translucent electrode, or a reflective electrode. When the second light-emitting electrode 134 is a transmissive electrode, the second light-emitting electrode 134 may be made of a transparent metal oxide such as indium tin oxide (ITO), indium zinc oxide (IZO), zinc oxide (ZnO) and indium tin zinc oxide (ITZO).

When the second light-emitting electrode 134 is a translucent electrode or a reflective electrode, the second light-emitting electrode 134 may include Ag, Mg, Cu, Al, Pt, Pd, Au, Ni, Nd, Ir, Cr, Li, Ca, LiF/Ca, LiF/Al, Mo, Ti, Yb, or a compound containing them (e.g., AgYb, AgMg and MgAg compounds depending on the content, or the like), or a mixture (e.g., a mixture of Ag and Mg). Alternatively, the second light-emitting electrode 134 may have a multi-layer structure including a reflective film or translucent film formed with the above materials and a transparent conductive film formed with ITO (indium tin oxide), IZO (indium zinc oxide), ZnO (zinc oxide), ITZO (indium tin zinc oxide), or the like

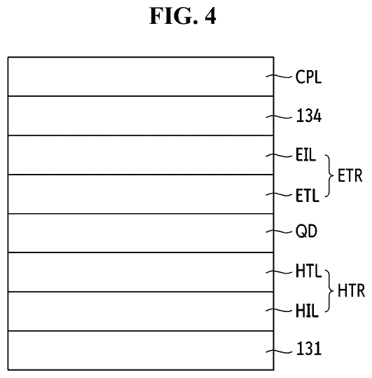

FIG. 4 is an enlarged cross-sectional view of area LE of FIG. 3, showing the structure of a light-emitting element according to a first embodiment.

The light-emitting element LE may include a first light-emitting electrode 131, an emissive layer 133 including a hole injection layer HIL, a hole transport layer HTL, a quantum-dot emissive layer QD, an electron transport layer ETL and an electron injection layer EIL, and a second light-emitting electrode 134.

The hole injection layer HIL and/or the hole transport layer HTL may include an organic material.

The electron transport layer ETL and/or the electron injection layer EIL may include a metal oxide.

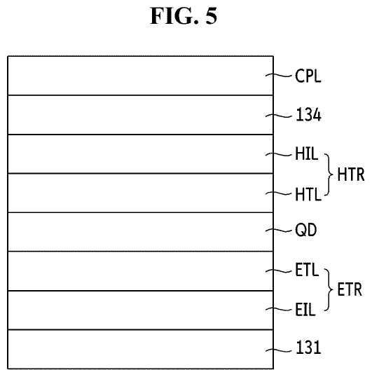

A first emissive layer 1331 may include a first hole injection layer HIL1, a first hole transport layer HTL1, a first quantum-dot emissive layer QD1, a first electron transport layer ETL1, and a first electron injection layer EIL1. A second emissive layer 133_2 may include a second hole injection layer HIL2, a second hole transport layer HTL2, a second quantum-dot emissive layer QD2, a second electron transport layer ETL2, and a second electron injection layer EIL2. A third emissive layer 133_2 may include a third hole injection layer HIL3, a third hole transport layer HTL3, a third quantum-dot emissive layer QD3, a third electron transport layer ETL3, and a third electron injection layer EIL3. FIG. 5 is an enlarged cross-sectional view of area LE of FIG. 3, showing the structure of a light-emitting element according to a second embodiment.

FIG. 5 shows a structure in which the hole injection layer HIL and the hole transport layer HTL are reversed with the electron transport layer ETL and the electron injection layer EIL of FIG. 4. In the reversed structure as shown in FIG. 5, the first light-emitting electrode 131 may be a cathode, and the second light-emitting electrode 134 may be an anode.

The light-emitting element LE may further include a capping layer CPL on the second light-emitting electrode 134. The capping layer CPL may include multiple layers or a single layer.

According to an embodiment of the present disclosure, the capping layer CPL may be an organic layer or an inorganic layer. For example, when the capping layer CPL includes an inorganic material, the inorganic material may include an alkali metal compound such as LiF, an alkaline earth metal compound such as MgF₂, SiON, SiNX, SiOy, or the like.

The encapsulation layer 140 may include a first inorganic encapsulation layer 141 on the element layer 130 and containing an inorganic material, an organic encapsulation layer 142 on the first inorganic encapsulation layer 141, and a second inorganic encapsulation layer 143 on the organic encapsulation layer 142 and containing an inorganic material.

By virtue of the encapsulation layer 140, the defects on the circuit layer 120 or the element layer 130 due to foreign substances may be reduced, and the defects by oxygen or moisture permeating into the circuit layer 120 or the element layer 130 may be delayed or prevented.

The encapsulation layer 140 may be on the second light-emitting electrode 134. In addition, when the light-emitting element LE according to the embodiment includes the capping layer CPL, the encapsulating layer 140 may be placed on the capping layer CPL.

The encapsulation layer 140 may be a stack of multiple layers. The encapsulation layer 140 according to the embodiment may include at least one organic layer (hereinafter referred to as organic encapsulation layer) and at least one inorganic layer (hereinafter referred to as inorganic encapsulation layer).

The first inorganic encapsulation layer 141 may be placed on the second light-emitting electrode 134. When the light-emitting element LE further includes the capping layer CPL, the first inorganic encapsulation layer 141 may be placed on the capping layer CPL.

The first inorganic encapsulating layer 141 may protect the light-emitting element LE from moisture and oxygen. The first inorganic encapsulation layer 141 includes an inorganic material and thus has a high film density. It may have a large bond with a functional layer under the first inorganic encapsulation layer 141. Accordingly, it is possible to prevent moisture or oxygen from permeating into the interface between the first inorganic encapsulation layer 141 and a functional layer under the first inorganic encapsulating layer 141, e.g., the second light-emitting electrode 134 or the capping layer CPL. In addition, it is possible to prevent separation of the first inorganic encapsulation layer 141. The first inorganic encapsulation layer 141 may include at least one of: silicon nitride, silicon oxynitride, silicon oxide, titanium oxide, and aluminum oxide.

The organic encapsulation layer 142 may be on the first inorganic encapsulation layer 141. The organic encapsulation layer 142 may protect the display device 10 from foreign substances such as dust particles. The organic encapsulation layer 142 may have a flat upper surface. The organic encapsulation layer 142 may provide a flat surface over the first inorganic encapsulation layer 141 having different heights. The organic encapsulation layer 142 may be provided to reduce the height differences of the upper surface of the first inorganic encapsulation layer 141 so that a functional layer may be placed evenly on the upper surface. According to an embodiment of the present disclosure, the thickness of the organic encapsulation layer 142 may be greater than the thickness of the first inorganic encapsulation layer 141. In addition, the thickness of the organic encapsulation layer 142 may be greater than the thicknesses of the first inorganic encapsulation layer 141 and the thickness of the second inorganic encapsulation layer 143. The organic encapsulation layer 142 may include a polymer resin.

The second inorganic encapsulation layer 143 may be placed on the organic encapsulation layer 142. The second inorganic encapsulation layer 143 may include an inorganic material. The second inorganic encapsulation layer 143 may protect the display device 10 from moisture and oxygen. The second inorganic encapsulation layer 143 has high bonding strength with the organic encapsulation layer 142, and thus it is possible to prevent moisture and oxygen from permeating into the interface between the second inorganic encapsulation layer 143 and the organic encapsulation layer 142.

Although not shown in the drawings, the encapsulation layer 140 may further include an additional organic encapsulation layer and an additional inorganic encapsulation layer on the second inorganic encapsulation layer 143. The encapsulation layer 140 may further include n additional organic encapsulation layers and n additional inorganic encapsulation layers, where n is a natural number equal to or greater than 1. The n additional organic encapsulation layers and the n additional inorganic encapsulation layers may be arranged alternately. The n additional organic encapsulation layers may have a thickness greater than that of the n additional inorganic encapsulation layers on average. It should be understood, however, that the embodiments of the present disclosure are not limited thereto. The materials of the additional organic encapsulation layers and the additional inorganic encapsulation layers may be identical to those of the organic encapsulation layer 142, the first inorganic encapsulation layer 141 and the second inorganic encapsulation layer 143 described above.

The color filter layer 150 may be placed on the encapsulation layer 140. The color filter layer 150 may selectively transmit light from each of the emission areas EA emitted from the light-emitting element LE in each of the emission areas EA.

The color filter layer 150 may include a first filter portion 151 that is arranged in the first emission area EA1 and transmits light in the first wavelength range, a second filter portion 152 that is arranged in the second emission area EA2 and transmits light in the second wavelength range a third filter portion 153 that is arranged in the third emission area EA3 and transmits light in the third wavelength range, and a light-blocking portion 154 that is arranged in the non-emission area NEA and the non-display area NDA (see FIG. 1) and blocks light.

Each of the first filter portion 151, the second filter portion 152 and the third filter portion 153 may include a colorant such as a dye and a pigment. A colorant may be a material that absorbs light in a wavelength range other than certain wavelength ranges.

That is to say, the first filter portion 151 may include a colorant that absorbs light in other wavelength ranges than the first wavelength range among the lights emitted from the light-emitting element LE, thereby transmitting light in the first wavelength range.

The second filter portion 152 may include a colorant that absorbs light in other wavelength ranges than the second wavelength range among the lights emitted from the light-emitting element LE, thereby transmitting light in the second wavelength range.

The third filter portion 153 may include a colorant that absorbs light in other wavelength ranges than the third wavelength range among the lights emitted from the light-emitting element LE, thereby transmitting light in the third wavelength range.

The light-blocking portion 154 may include a structure in which two or more of the first filter portion 151, the second filter portion 152 and the third filter portion 153 are stacked on one another.

Alternatively, the light-blocking portion 154 may include a material that absorbs light, such as a black matrix material.

A method for fabricating the display device according to the first embodiment may include: forming first electrodes 131 on a substrate SUB; forming emissive layers 133 on a first electrode 131; and treating the emissive layers 133 with an organic acid represented by Chemical Formula 1 below.

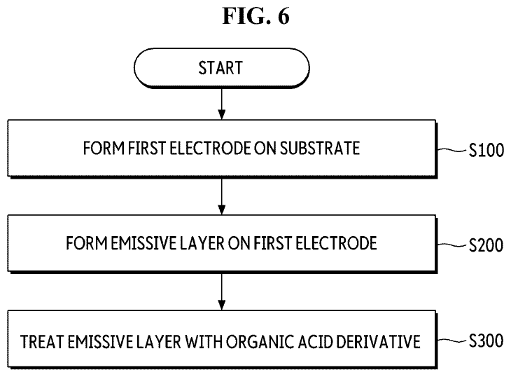

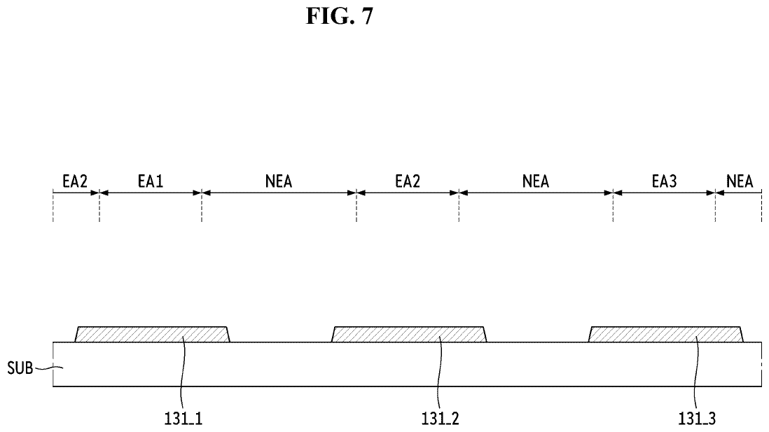

FIG. 6 is a flowchart for illustrating a method for fabricating a display device according to an embodiment of the present disclosure. FIG. 7 is a cross-sectional view showing a substrate and a plurality of first electrodes at step S100 of FIG. 6.

Initially, the first electrodes 131_1, 131_2 and 131_3 may be formed on the substrate SUB (step S100). The substrate SUB may be formed using the above-listed materials. The process for forming the first electrodes 131_1, 131_2 and 131_3 is not particularly limited herein.

Subsequently, a pixel-defining layer 132 covering the edges of the first electrodes 131 may be formed. The pixel-defining layer 132 may be formed using the above-listed materials.

The process for forming the pixel-defining layer 132 is not particularly limited herein.

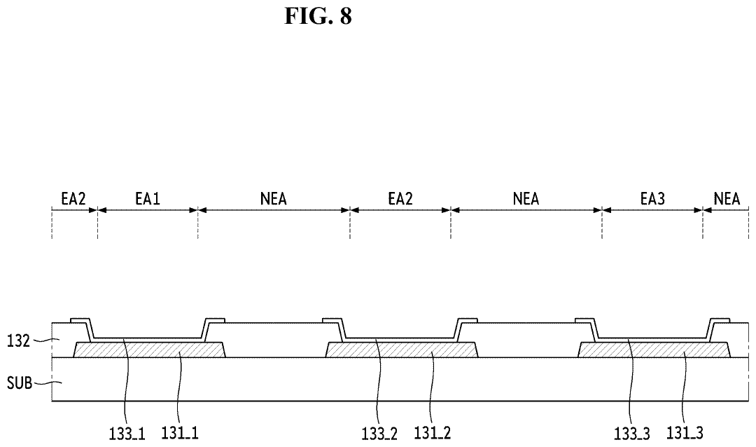

FIG. 8 is a cross-sectional view showing the substrate, the first electrodes, and the emissive layers at step S200 of FIG. 6.

Subsequently, emissive layers 133 may be formed on the first electrodes 131, respectively (step S200). The emissive layers 133 may be formed using the above-listed materials. A process for forming the emissive layers 133 is not particularly limited herein. In the first emission area EA1, a first emissive layer 1331 may be formed on the first light-emitting electrode 131_1. In the second emission area EA2, a second emissive layer 133_1 may be formed on the first light-emitting electrode 131_2. In the third emission area EA3, a third emissive layer 133_3 may be formed on the first light-emitting electrode 131_3. A pixel-defining layer 132 may be formed in the non-emission area NEA in order to define the emission areas EA.

Subsequently, the emissive layers 133 may be treated with an organic acid (step S300).

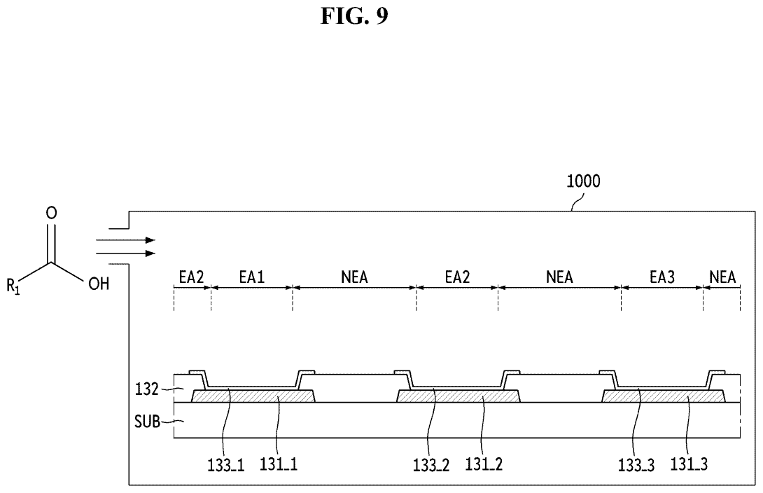

FIG. 9 is a view showing injecting the organic acid into a reaction space where the substrate on which emissive layers are formed is placed at step S300 of FIG. 6.

The organic acid may be represented by Chemical Formula 1 below:

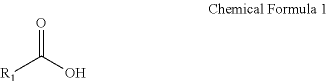

where R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

In some embodiments R₁ is H, a substituted or unsubstituted C₁₋₈ linear or branched alkyl group, or a substituted or unsubstituted C₂₋₈ linear or branched alkenyl group. In some embodiments R₁ is a substituted or unsubstituted C₁₋₈ linear or branched alkyl group, or an unsubstituted C₂₋₈ linear or branched alkenyl group.

The organic acid may include an organic acid represented by one of A1 to A12 below:

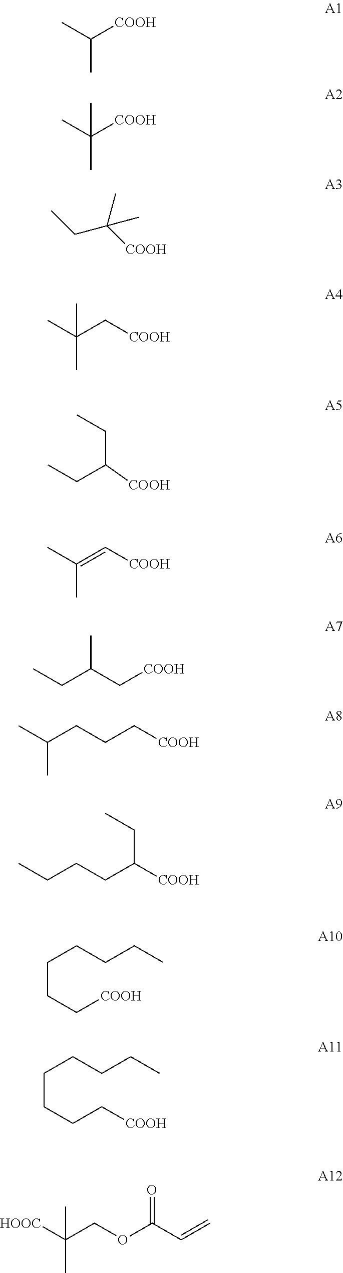

The flash point of the organic acid may be 70° C. or lower at atmospheric pressure.

When the flash point of the organic acid of the present disclosure is 70° C. or lower at atmospheric pressure, a low-temperature process may be possible.

The acid dissociation constant (pKa) of the organic acid may be 1.0 to 5.5. If the acid dissociation constant of the organic acid satisfies the above range, the effect of improving the emission efficiency of the light-emitting element LE may be improved.

The concentration of the organic acid may be equal to or less than 10 wt %, based on an acid solution comprising the organic acid. If the concentration of the organic acid is higher than 10 wt %, the light-emitting element LE may be deteriorated by excessive acid.

The treating with the organic acid may include: placing the substrate SUB on which the emissive layer 133 is formed inside a reaction space 1000; and vaporizing the organic acid at a temperature of 70° C. or lower to injecting it into the reaction space 1000.

The reaction space 1000 may be a vacuum chamber dryer (VCD) or a vapor chamber.

The reaction space 1000 may be at a reduced pressure. An inert gas such as nitrogen and argon may be injected into the reaction space 1000.

When the flash point of the organic acid used herein is 70° C. or lower at atmospheric pressure, it may be vaporized at a temperature of 70° C. or lower at atmospheric pressure or lower.

The treating with the organic acid may be performed for 30 minutes to 120 hours.

If the time taken for treating with the organic acid is less than 30 minutes, the emissive layers 133 may not be sufficiently treated with the organic acid. If the time taken for treating with the organic acid is longer than 120 hours, the light-emitting element LE may be deteriorated by excessive acid.

The vaporized organic acid may form a passivation layer on the emissive layers 133 to suppress surface defects.

If the emissive layers 133 are excessively treated with the organic acid, damage to the light-emitting element LE may increase during an aging process, which may deteriorate the characteristics of the light-emitting element LE. According to the present disclosure, since only the target layer is treated with the vapor of the organic acid, it is possible to prevent excessive acid treatment. In particular, if the encapsulation layer 140 containing an acid is on the light-emitting element LE, the acid of the encapsulation layer 140 may leak into the light-emitting element LE, and thus the deterioration of the light-emitting element LE may increase. In contrast, according to the present disclosure, it is possible to prevent excessive acid treatment because acid treatment is performed only during the fabricating process.

A method for fabricating the display device according to the second embodiment may include: forming a first electrode 131 on a substrate SUB; forming a first emissive layer 133_1 that emits light of a first wavelength range in a first emission area EA1; treating the first emissive layer 133_1 with an organic acid derivative; forming a second emissive layer 133_2 that emits light of a second wavelength range in a second emission area EA2; treating the first emissive layer 133_1 and the second emissive layer 133_2 with an organic acid derivative; forming a third emissive layer 133_3 that emits light of a third wavelength range in a third emission area EA3; and treating the first emissive layer 133_1, the second emissive layer 133_2 and the third emissive layer 133_3 with an organic acid derivative.

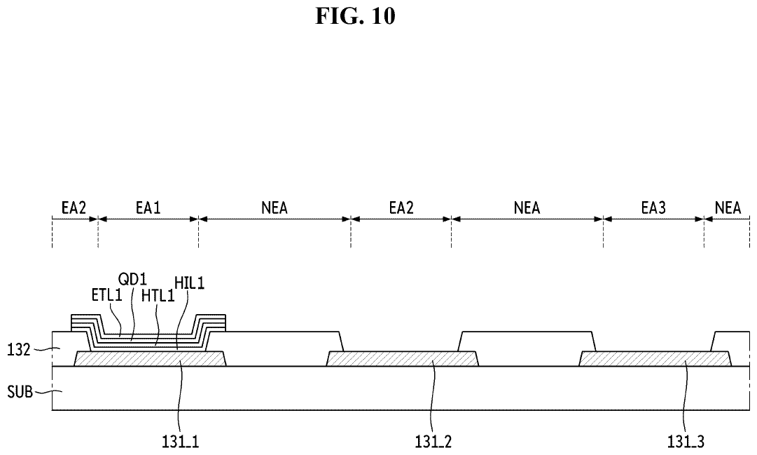

FIG. 10 is a cross-sectional view showing a first electrode, a first hole injection layer, a first hole transport layer, a first quantum-dot emissive layer, and a first electron transport layer in a first emission area. Referring to FIG. 10, a first hole injection layer HIL1, a first hole transport layer HTL1, a first quantum-dot emissive layer QD1, and a first electron transport layer ETL1 are formed in a first emission area EA1 on a substrate SUB.

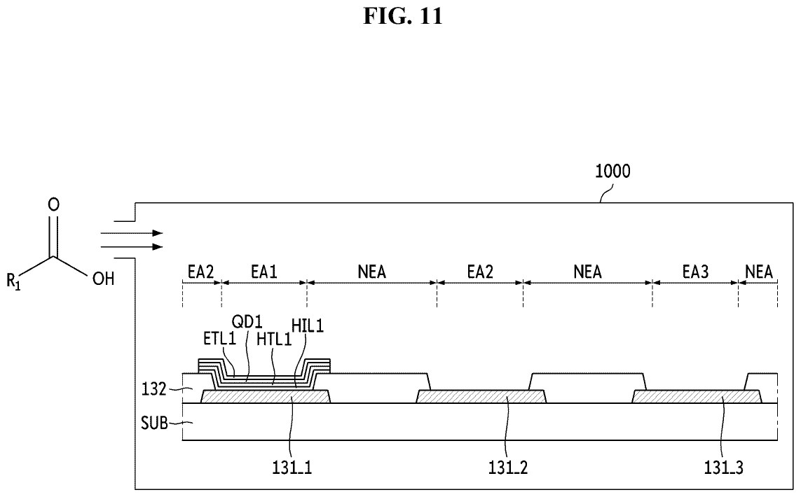

FIG. 11 is a view showing injecting the organic acid into a reaction space where a substrate is placed, on which a first electrode, a first hole injection layer, a first hole transport layer, a first quantum-dot emissive layer, and a first electron transport layer are formed in a first emission area.

Referring to FIG. 11, if the organic acid is injected when a second emissive layer 133_2 of a second emission area EA2 and a third emissive layer 133_3 of a third emission area EA3 are not formed while only the first emissive layer 133_1 of the first emission area EA1 is formed, only the first emissive layer 131_1 may be treated with the organic acid derivative.

The organic acid injected into the reaction space 1000 may diffuse not only to the first electron transport layer ETL1 at the top but also to the first quantum-dot emissive layer QD1. It should be noted that the organic materials of the first hole transport layer HTL1 and the first hole injection layer HIL1 may be oxidized by the acid component of the organic acid derivative. The amount of the injected organic acid may be adjusted so that it does not diffuse to the first hole transport layer HTL1 and the first hole injection layer HILL. The amount of the injected organic acid may be controlled by adjusting the concentration of the organic acid, the injection time, the heating temperature, or the like

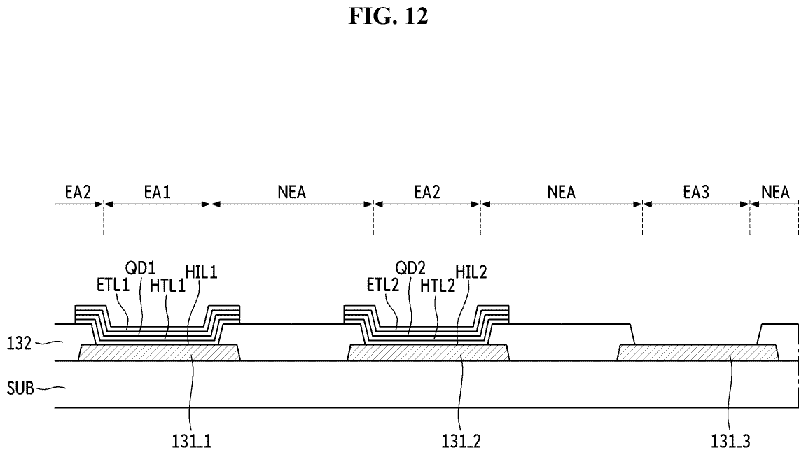

FIG. 12 is a cross-sectional view showing a first electrode, a second hole injection layer, a second hole transport layer, a second quantum-dot emissive layer, and a second electron transport layer in a second emission area.

Referring to FIG. 12, a second hole injection layer HIL2, a second hole transport layer HTL2, a second quantum-dot emissive layer QD2, and a second electron transport layer ETL2 are formed in the second emission area EA2 on the substrate SUB.

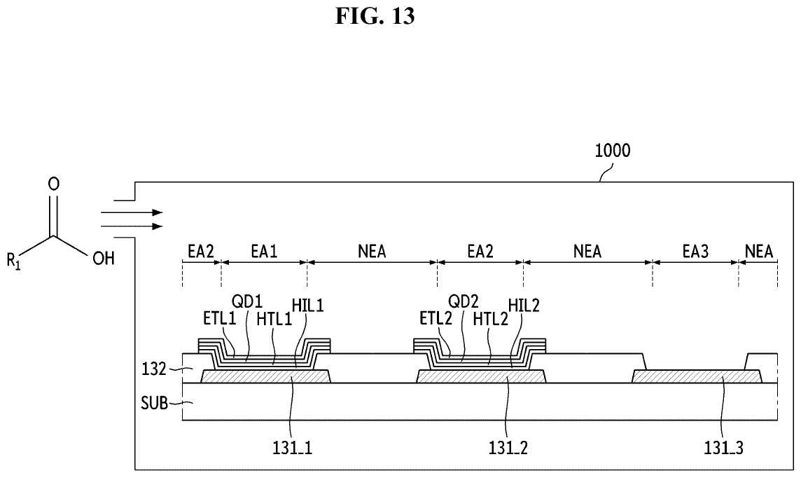

FIG. 13 is a view showing injecting the organic acid into the reaction space where the substrate is placed, on which a first electrode, a second hole injection layer, a second hole transport layer, a second quantum-dot emissive layer, and a second electron transport layer are formed in the second emission area.

Referring to FIG. 13, to treat with an organic acid a substrate SUB on which first electrodes 131_1 and 131_2, a first hole injection layer HIL1, a first hole transport layer HTL1, a first quantum-dot emissive layer QD1 and a first electron transport layer ETL1 of a first emission area EA1, and a second hole injection layer HIL2, a second hole transport layer HTL2, a second quantum-dot emissive layer QD2 and a second electron transport layer ETL2 of a second emission area EA2 are formed, a first emissive layer 133_1 of the first emission area EA1 and a second emissive layer 133_2 of the second emission area EA2 may be treated with the organic acid. The organic acid for each treatment may be the same or different from the other organic acid.

The organic acid injected into the reaction space 1000 may diffuse not only to the first electron transport layer ETL1 and the second electron transport layer ETL2 at the top but also to the first quantum-dot emissive layer QD1 and the second quantum-dot emissive layer QD2. It should be noted that the organic materials of the first hole transport layer HTL1, the first hole injection layer HIL1, the second hole transport layer HTL2 and the second hole injection layer HIL2 may be oxidized by the acid component of the organic acid. For this reason, the amount of the injected organic acid may be adjusted so that the organic acid does not diffuse to the first hole transport layer HTL1, the first hole injection layer HIL1, the second hole transport layer HTL2 and the second hole injection layer HIL2.

Since the first electron transport layer ETL1 and the first quantum-dot emissive layer QD1 were previously treated with the organic acid, the degree to which the first electron transport layer ETL1 and the first quantum-dot emissive layer QD1 were treated with the organic acid may be greater than the degree to which the second electron transport layer ETL2 and the second quantum-dot emissive layer QD2 were treated with the organic acid derivative.

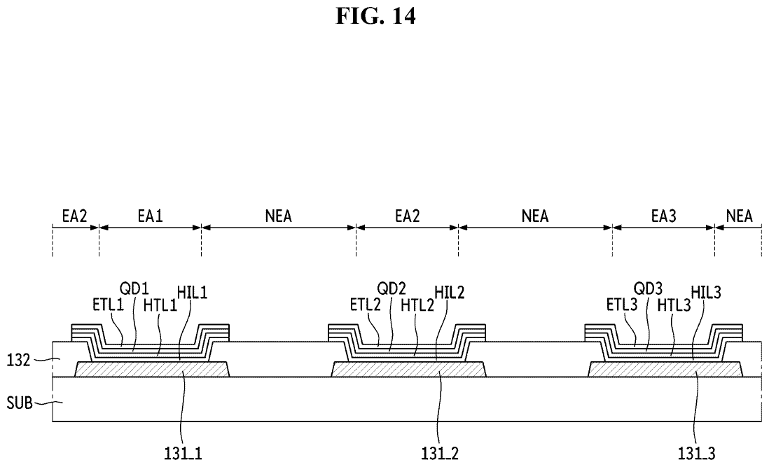

FIG. 14 is a cross-sectional view showing a first electrode, a third hole injection layer, a third hole transport layer, a third quantum-dot emissive layer, and a third electron transport layer in a third emission area.

Referring to FIG. 14, a third hole injection layer HIL3, a third hole transport layer HTL3, a third quantum-dot emissive layer QD3, and a third electron transport layer ETL3 are formed in the third emission area EA3 on the substrate SUB.

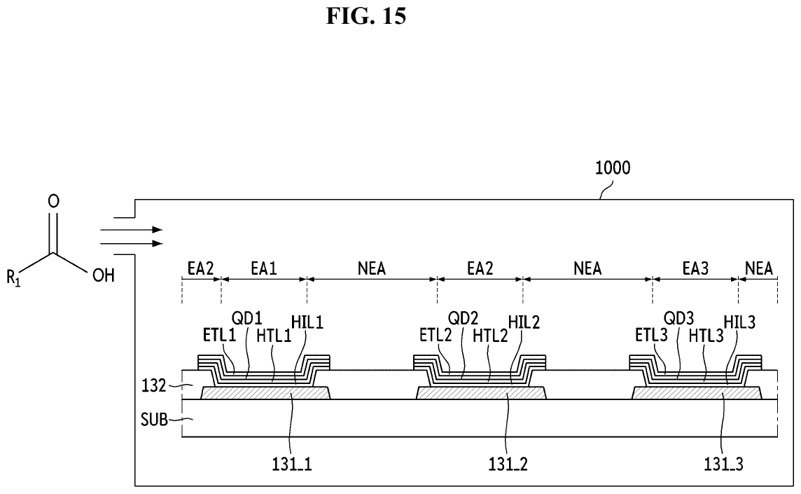

FIG. 15 is a view showing injecting the organic acid into the reaction space where the substrate is placed, on which a first electrode, a third hole injection layer, a third hole transport layer, a third quantum-dot emissive layer, and a third electron transport layer are formed in a third emission area.

Referring to FIG. 15, to treat with an organic acid a substrate SUB on which first electrodes 131_1, 131_2 and 131_3, a first hole injection layer HIL1, a first hole transport layer HTL1, a first quantum-dot emissive layer QD1 and a first electron transport layer ETL1 of a first emission area EA1, a second hole injection layer HIL2, a second hole transport layer HTL2, a second quantum-dot emissive layer QD2 and a second electron transport layer ETL2 of a second emission area EA2, and a third hole injection layer HIL3, a third hole transport layer HTL3, a third quantum-dot emissive layer QD3 and a third electron transport layer ETL3 of a third emission area EA3 are formed, a first emissive layer 133_1 of the first emission area EA1, a second emissive layer 133_2 of the second emission area EA2 and a third emissive layer 133_3 may be treated with the organic acid derivative. The organic acid for each treatment may be the same or different from each of the other organic acid(s).

The organic acid injected into the reaction space 1000 may diffuse not only to the first electron transport layer ETL1, the second electron transport layer ETL2 and the third electron transport layer ETL3 at the top but also to the first quantum-dot emissive layer QD1, the second quantum-dot emissive layer QD2 and the third quantum-dot emissive layer QD3. It should be noted that the organic materials of the first hole transport layer HTL1, the first hole injection layer HIL1, the second hole transport layer HTL2, the second hole injection layer HIL2, the third hole transport layer HTL3 and the third hole injection layer HIL3 may be oxidized by the acid component of the organic acid derivative. Accordingly, the amount of the injected organic acid may be adjusted so that it does not diffuse to the first hole transport layer HTL1, the first hole injection layer HIL1, the second hole transport layer HTL2, the second hole injection layer HIL2, the third hole transport layer HTL3 and the third hole injection layer HIL3.

Since the first electron transport layer ETL1, the first quantum-dot emissive layer QD1, the second electron transport layer ETL2 and the second quantum-dot emissive layer QD2 were previously treated with the organic acid, the degree to which the first electron transport layer ETL1, the first quantum-dot emissive layer QD1, the second electron transport layer ETL2 and the second quantum-dot emissive layer QD2 were treated with the organic acid may be greater than the degree to which the third electron transport layer ETL3 and the third quantum-dot emissive layer QD3 were treated with the organic acid derivative.

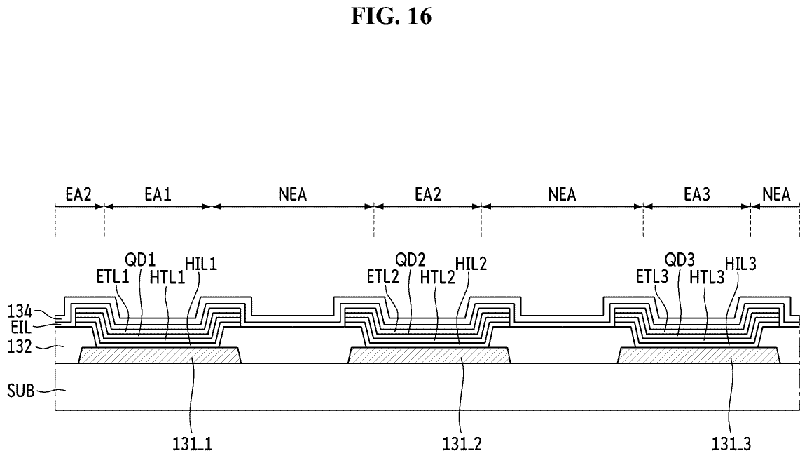

FIG. 16 is a cross-sectional view showing a first electrode, a hole injection layer, a hole transport layer, a quantum-dot emissive layer, an electron transport layer, an electron injection layer, and a second electrode.

Subsequently, an electron injection layer EIL may be formed on the first electron transport layer ETL1, the second electron transport layer ETL2, and the third electron transport layer ETL3. Subsequently, a second electrode 134 may be formed on the electron injection layer EIL.

In the display device 10 fabricated by the method for fabricating the display device according to the second embodiment, the degree to which the first emissive layer 133_1 is treated with the organic acid, the degree to which the second emissive layer 133_2 is treated with the organic acid, and the degree to which the third emissive layer 133_3 is treated with the organic acid are different from one another. According to the method described herein, the degree to which the first emissive layer 133_1 is treated with the organic acid may be the greatest, while the degree to which the third emissive layer 1333 is treated with the organic acid may be the least. Depending on the order of the method, the degree to which the first emissive layer 133_1 is treated with the organic acid, the degree to which the second emissive layer 133_2 is treated with the organic acid, and the degree to which the third emissive layer 133_3 is treated with the organic acid may be different from one another.

The quantum dots of the first emissive layer 1331, the quantum dots of the second emissive layer 133_2 and the quantum dots of the third emissive layer 1333 may have different amounts of acid required for aging. According to the present disclosure, it is possible to control the degree of the treatment with the organic acid by adjusting the order of forming the emissive layers 133. When the method of the present disclosure may adjust the degree of the treatment with the organic acid derivative depending on different regions, the emission efficiency may be improved.

Since the hole transport layer HTL and the hole injection layer HIL contain an organic material, the hole transport layer HTL and the hole injection layer HIL may be damaged by acid when exposed to the acid. Even though the hole transport layers HTL and the hole injection layers HIL are arranged at the lower portion of the emissive layers 133 according to the second embodiment, it is possible to prevent the organic acid derivative from diffusing into the hole transport layers HTL and the hole injection layers HIL by controlling the concentration and injection time of the organic acid derivative.

A method for fabricating a display device according to the third embodiment may include: sequentially forming an electron injection layer EIL and an electron transport layer ETL on a first electrode 131; treating the electron transport layer ETL with an organic acid derivative; forming a quantum-dot emissive layer QD on the electron transport layer ETL treated with the organic acid derivative; sequentially forming a hole transport layer HTL and a hole injection layer HIL on the quantum-dot emissive layer QD; and forming a second electrode 134 on the hole injection layer. The display device 10 fabricated according to the second embodiment may include the light-emitting element LE of FIG. 5.

The electron transport layer ETL may include a metal oxide. Since the metal oxide has oxygen vacancy defects, holes may leak, and thus the durability of the display device 10 may decrease. According to the present disclosure, the electron transport layer ETL is treated with the organic acid derivative to form the passivation layer on the metal oxide, thereby suppressing surface defects of the metal oxide. In addition, charge balance may be improved, leakage current may be reduced, and the quenching phenomenon may be suppressed in the light-emitting element LE.

In the method for fabricating the display device according to the second embodiment, the treatment of the organic acid derivative is performed when the first electrode 131, the electron injection layer EIL, and the electron transport layer ETL are formed. Accordingly, the hole transport layer HTL and the hole injection layer HIL containing the organic material are not treated with the organic acid, and thus damage caused by the acid may be avoided.

The second electrode 134 may be formed using the above-listed materials. A process for forming the second electrode 134 is not particularly limited herein.

Subsequently, the method may further include forming an encapsulation layer 140 on the second electrode 134. The encapsulation layer 140 may be formed using the above-listed materials. The process for forming the encapsulation layer 140 is not particularly limited herein.

Hereinafter, the embodiments of the present disclosure will be described in more detail. It should be understood that the embodiments of the present disclosure are merely illustrative and are not intended to limit the scope of the present disclosure.

### 1. Fabrication of Light-Emitting Element

### 1) Example 1

ITO was formed on a substrate as a first electrode. An emissive layer including quantum dots was formed on the first electrode. The substrate having the emissive layer formed thereon was placed inside a vacuum chamber dryer (VCD). The inside of the VCD was formed under reduced pressure in nitrogen atmosphere. Isobutyric acid was vaporized for five hours at the temperature of 60° C., and the vaporized isobutyric acid was injected into the VCD to treat the emissive layer with the acid. After taking the substrate out of the VCD, a second electrode was formed on the emissive layer to fabricate a light-emitting element.

### 2) Comparative Example 1

A light-emitting element identical to that of Example 1 was fabricated, except that the emissive layer was not treated with acid.

### 3) Comparative Example 2

ITO was formed on a substrate as a first electrode. An emissive layer including quantum dots was formed on the first electrode. A second electrode was formed on the emissive layer. An encapsulation layer containing isobutyric acid was formed on the second electrode, to fabricate a light-emitting element. The light-emitting element was heat-treated at the temperature of 60° C. for five hours to perform positive aging.

### Evaluation

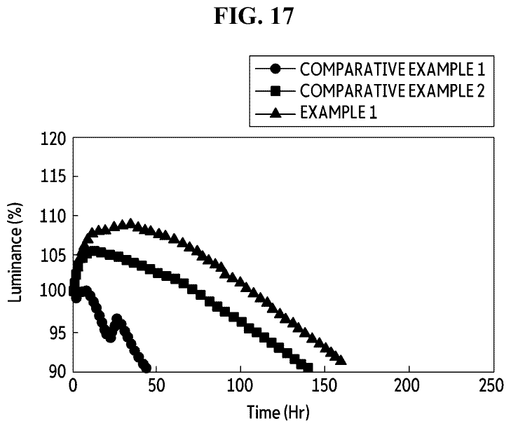

FIG. 17 is a graph showing the luminance over time of the light-emitting elements of Example 1, Comparative Example 1, and Comparative Example 2.

It may be seen from the results shown in FIG. 17 that the luminance increases in the order of Example 1, Comparative Example 2 and Comparative Example 1.

The efficiency and lifespan of the light-emitting elements of Example 1, Comparative Example 1 and Comparative Example 2 are shown in Table 1 below:

TABLE 1

| | Positive | Efficiency | Lifespan |
|---|---|---|---|
| | Aging | (cd/A) | (T90) |
| Example 1 | Fume Treatment | 11.6 | 170 |
| Comparative Example 1 | N/A | 6.0 | 50 |
| Comparative Example 2 | Encapsulation | 10.4 | 140 |

In Table 1, the efficiency represents current efficiency expressed in luminance (candela) per ampere, and the lifespan represents the time when the luminance decreases to 90 from the initial luminance of 100. It may be seen from the results shown in Table 1 that Example 1 exhibited the highest efficiency and lifespan.

It may be seen from the results shown in FIG. 17 and Table 1 that the characteristics of the light-emitting elements of Example 1 and Comparative Example 2, which were subject to acid treatment, are better than those of Comparative Example 1, which was not subject to aging. In addition, it may be seen that the fume treatment (Example 1), in which acid treatment is performed on the emissive layer during the fabrication process, exhibited higher efficiency and lifespan than those of the encapsulation method (Comparative Example 2), in which acid is included in the encapsulation layer. In the encapsulation method, the acid remains inside the encapsulation layer and thus the acid inside the encapsulation layer may leak over time. As a result, the light-emitting element may deteriorate. In contrast, in the fume treatment, only the necessary amount of acid is used during the fabrication process and no additional acid treatment is performed. As a result, the emissive layer's efficiency and lifespan of the light-emitting element may be improved.

The display device according to the embodiment may be applied to a variety of electronic devices. An electronic device according to an embodiment includes the display device described above, and may further include a module or device having additional features in addition to the display device.

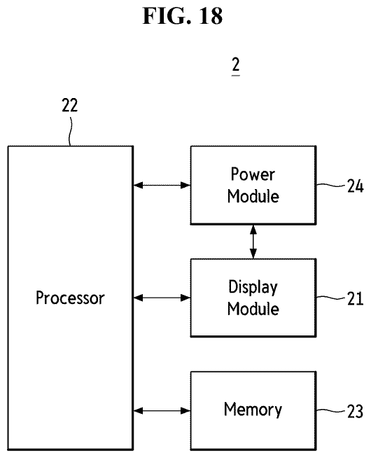

FIG. 18 is a block diagram of an electronic device according to an embodiment of the present disclosure. Referring to FIG. 18, an electronic device 2 according to an embodiment of the present disclosure may include a display module 21, a processor 22, a memory 23, and a power module 24.

The processor 22 may include at least one of: a central processing unit (CPU), an application processor (AP), a graphic processing unit (GPU), a communication processor (CP), an image signal processor (ISP), and a controller.

The memory 23 may store data information required for the operation of the processor 22 or the display module 21. When the processor 22 executes an application stored in the memory 23, an image data signal and/or an input control signal may be transmitted to the display module 21. The display module 21 may process the received signal and output image information through a display screen.

The power module 24 may include a power supply module such as a power adapter and a battery device, and a power conversion module that converts the power supplied by the power supply module to generate power required for the operation of the electronic device 20.

At least one of the elements of the electronic device 2 described above may be included in the display device 10 according to the embodiments described above. In addition, some of the individual modules functioning as a single module may be included in the display device 10 while some others may be provided separately from the display device 10. For example, the display device 10 may include the display module 21, and the processor 22, the memory 23 and the power module 24 may be provided as other devices inside the electronic device 2 than the display device 10.

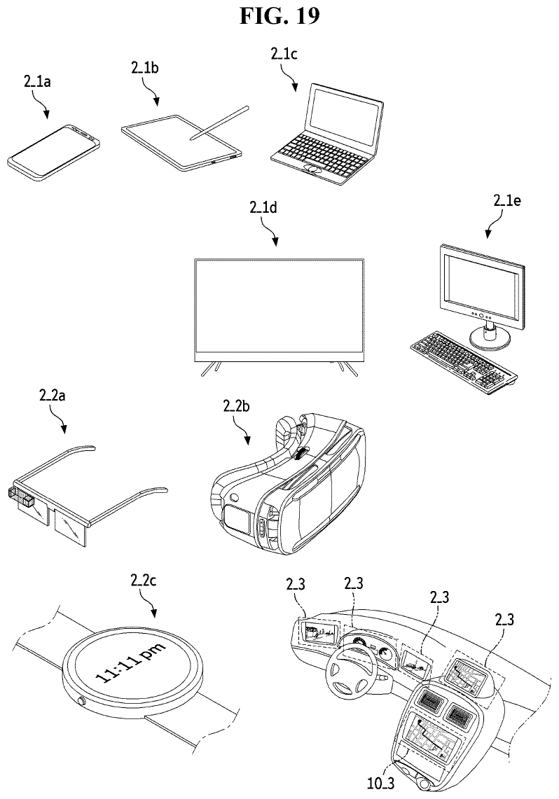

FIG. 19 is a view showing electronic devices according to a variety of embodiments of the present disclosure.

Referring to FIG. 19, a variety of electronic devices 2 employing the display devices according to the embodiments may include not only electronic devices for display images such as a smart phone 2_1a, a tablet PC 2_1b, a laptop computer 2_1c, a TV 2_1d and a desktop monitor 2_1e, but also wearable electronic devices including display modules such as smart glasses 2_2a, a head-mounted display 2_2b and a smart watch 2_2c, and electronic devices for vehicles 2_3 including display modules such as a center information display (CID) placed on the dashboard, the center fascia and the dashboard of a vehicle, and a room mirror display.

Although the embodiments of the present invention have been described with reference to the attached drawings, those skilled in the art will understand that the present invention may be implemented in other specific forms without changing the technical idea or essential features of the present invention. Therefore, it should be understood that the embodiments described above are exemplary in all respects and not restrictive.

What is claimed is:

1. A method for fabricating a display device, the method comprising:
forming a first electrode on a substrate;
forming an emissive layer on the first electrode; and
treating the emissive layer with an organic acid represented by the following chemical formula: 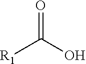
wherein R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

2. The method of claim 1, wherein a concentration of an acid solution comprising the organic acid is equal to or less than 10 weight percent.

3. The method of claim 1, wherein an acid dissociation constant of the organic acid is 1.0 to 5.5.

4. The method of claim 1, wherein the treating of the emissive layer with the organic acid comprises:
placing the substrate having the emissive layer formed thereon inside a reaction space; and
vaporizing the organic acid at a temperature of 70° C. or lower and injecting it into the reaction space.

5. The method of claim 4, wherein the reaction space is a vacuum chamber dryer or a vapor chamber.

6. The method of claim 1, wherein the treating of the emissive layer with the organic acid is performed for 30 minutes to 120 hours.

7. The method of claim 1, wherein the forming of the emissive layer on the first electrode, and treating the emissive layer with the organic acid comprise:
forming a first emissive layer emitting light of a first wavelength range in a first emission area;
treating the first emissive layer with the organic acid;
forming a second emissive layer emitting light of a second wavelength range in a second emission area;
treating the first emissive layer and the second emissive layer with the organic acid;
forming a third emissive layer emitting light of a third wavelength range in a third emission area; and
treating the first emissive layer, the second emissive layer and the third emissive layer with the organic acid.

8. The method of claim 7, wherein the first wavelength range is lower than the second wavelength range, and the second wavelength range is lower than the third wavelength range.

9. The method of claim 7, wherein the first emissive layer comprises a first hole transport layer, a first hole injection layer, a first quantum-dot emissive layer, a first electron transport layer and a first electron injection layer,
wherein the second emissive layer comprises a second hole transport layer, a second hole injection layer, a second quantum-dot emissive layer, a second electron transport layer, and a second electron injection layer, and
wherein the third emissive layer comprises a third hole transport layer, a third hole injection layer, a third quantum-dot emissive layer, a third electron transport layer, and a third electron injection layer.

10. The method of claim 9, wherein the forming of the emissive layer on the first electrode, and treating the emissive layer with the organic acid comprise:
sequentially forming the first hole injection layer, the first hole transport layer, the first quantum-dot emissive layer, and the first electron transport layer on the first electrode in the first emission area;
treating the first electron transport layer with the organic acid;
sequentially forming the second hole injection layer, the second hole transport layer, the second quantum-dot emissive layer, and the second electron transport layer on the first electrode in the second emission area;
treating the second electron transport layer with the organic acid;
sequentially forming the third hole injection layer, the third hole transport layer, the third quantum-dot emissive layer, and the third electron transport layer on the first electrode in the third emission area; and
treating the third electron transport layer with the organic acid.

11. The method of claim 10, wherein the forming of the emissive layer further comprises: forming an electron injection layer on the first electron transport layer, the second electron transport layer, and the third electron transport layer.

12. The method of claim 1, wherein the forming of the emissive layer, and treating the emissive layer with the organic acid comprise:
sequentially forming an electron injection layer and an electron transport layer on the first electrode; and
treating the electron transport layer with the organic acid.

13. The method of claim 12, further comprising:
sequentially forming a quantum-dot emissive layer, a hole transport layer and a hole injection layer on the electron transport layer.

14. The method of claim 12, wherein the electron transport layer comprises a metal oxide.

15. The method of claim 1, further comprising:
forming a second electrode on the emissive layer.

16. A display device comprising:
a substrate;
a first electrode on the substrate;
an emissive layer on the first electrode; and
a second electrode on the emissive layer,
wherein the emissive layer is treated with an organic acid represented by the following chemical formula,
wherein the emissive layer comprises:
a first emissive layer emitting light of a first wavelength range in a first emission area;
a second emissive layer emitting light of a second wavelength range in a second emission area; and
a third emissive layer emitting light of a third wavelength range in a third emission area, and
wherein a degree to which the first emissive layer is treated with the organic acid, a degree to which the second emissive layer is treated with the organic acid, and a degree to which the third emissive layer is treated with the organic acid are different from one another: 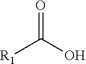
wherein R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.

17. The display device of claim 16, further comprising:
an electron transport region comprising a metal oxide located on the emissive layer.

18. The display device of claim 17, wherein the electron transport region comprises:
a first electron transport region in line with first emission area in a thickness direction of the substrate;
a second electron transport region in line with the second emission area in the thickness direction of the substrate; and
a third electron transport region in line with the third emission area in the thickness direction of the substrate.

19. The display device of claim 16, wherein a flash point of the organic acid is equal to or less than 70° C. at atmospheric pressure.

20. An electronic device comprising:
a display device providing images; and
a processor configured to transmit an image data signal to the display device,
wherein the display device is fabricated by:
forming a first electrode on a substrate;
forming an emissive layer on the first electrode; and
treating the emissive layer with an organic acid represented by the following chemical formula: 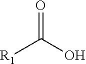
wherein R₁ is H, a substituted or unsubstituted C₁₋₈ linear or branched alkyl group, a substituted or unsubstituted C₂₋₈ linear or branched alkenyl group, a substituted or unsubstituted C₃₋₈ cycloalkyl group, a substituted or unsubstituted C₃₋₈ heterocycloalkyl group, a substituted or unsubstituted C₆₋₈ aryl group, or a substituted or unsubstituted C₆₋₈ heteroaryl group.
